(19) United States
(12) Patent Application Publication
(10) Pub. No.: US 2016/0204059 A1
(43) Pub. Date: Jul. 14, 2016

(54) Conductive Lines with Protective Sidewalls

(71) Applicant: SanDisk Technologies Inc., Plano, TX (US)

(72) Inventors: Noritaka Fukuo, Yokkaichi (JP); Takuya Futase, Yokkaichi (JP); Katsuo Yamada, Yokkaichi (JP); Yuji Takahashi, Yokkaichi (JP); Tomoyasu Kakegawa, Yokkaichi (JP)

(21) Appl. No.: 14/593,528

(22) Filed: Jan. 9, 2015

(51) Int. Cl. H01L 23/528; H01L 23/532; H01L 21/02; H01L 21/768; H01L 21/311

(52) U.S. Cl. CPC H01L 23/528; H01L 21/76802; H01L 21/76831; H01L 21/76834; H01L 21/7682; H01L 21/76877; H01L 21/7684; H01L 21/31111; H01L 21/02164; H01L 21/02271; H01L 21/02208; H01L 23/53238; H01L 21/76843; H01L 21/0217; H01L 21/02167; H01L 21/0214; H01L 23/5329; H01L 21/02247

(57) ABSTRACT

Trenches are formed partially through a sacrificial layer at locations where bit lines are to be formed with some sacrificial material overlying vias. The trenches are lined with a protective layer and then the trenches are extended to expose vias. Bit lines are formed. Then sacrificial material is removed from between bit lines while portions of the protective layer remain to protect the bit lines.

### BACKGROUND

This application relates generally to non-volatile semiconductor memories of the flash memory type, their formation, structure and use.

There are many commercially successful non-volatile memory products being used today, particularly in the form of small form factor cards, USB drives, embedded memory, and Solid State Drives (SSDs) which use an array of flash EEPROM cells. An example of a flash memory system is shown in FIG. 1, in which a memory cell array 1 is formed on a memory chip 12, along with various peripheral circuits such as column control circuits 2, row control circuits 3, data input/output circuits 6, etc.

One popular flash EEPROM architecture utilizes a NAND array, wherein a large number of strings of memory cells are connected through one or more select transistors between individual bit lines and a reference potential. A portion of such an array is shown in plan view in FIG. 2A. Although four floating gate memory cells are shown in each string, the individual strings typically include 16, 32 or more memory cell charge storage elements, such as floating gates, in a column. Control gate (word) lines labeled WL0-WL3 and string selection lines, Drain Select Line, “DSL” and Source Select Line “SSL” extend across multiple strings over rows of floating gates. An individual cell within a column is read and verified during programming by causing the remaining cells in the string to be turned on hard by placing a relatively high voltage on their respective word lines and by placing a relatively lower voltage on the one selected word line so that the current flowing through each string is primarily dependent only upon the level of charge stored in the addressed cell below the selected word line. That current typically is sensed for a large number of strings in parallel, thereby to read charge level states along a row of floating gates in parallel.

The top and bottom of the string connect to the bit line and a common source line respectively through select transistors (source select transistor and drain select transistor). Select transistors do not contain floating gates and are used to connect NAND strings to control circuits when they are to be accessed, and to isolate them when they are not being accessed.

NAND strings are generally connected by conductive lines in order to form arrays that may contain many NAND strings. At either end of a NAND string a contact area may be formed. This allows connection of the NAND string as part of the array. Metal contact plugs (or “vias”) may be formed over contact areas to connect the contact areas (and thereby connect NAND strings) to conductive metal lines that extend over the memory array (e.g. bit lines). FIG. 2A shows bit line contacts BL0-BL4 and common source line contacts at either end of NAND strings. Contacts to contact areas may be formed by etching contact holes through a dielectric layer and then filling the holes with metal to form vias. Metal lines, such as bit lines, extend over the memory array and in peripheral areas in order to connect the memory array and various peripheral circuits. Electrical contact between metal lines and vias occurs where horizontal metal lines intersect vertical contact plugs. These metal lines may be close together (particularly in the memory array area where bit lines may be very close) which tends to make processing difficult and provides a risk of capacitive coupling. The characteristics of such lines (e.g. resistance and coupling) and the quality of connections with vias may be significant factors for good memory operation.

Thus, there is a need for a memory chip manufacturing process that forms uniform low resistance conductive lines, such as bit lines, in close proximity in an efficient manner.

### SUMMARY

In some nonvolatile memories, bit lines are separated by air gaps in order to provide low bit line to bit line coupling. Bit lines may be formed in trenches in a sacrificial layer that is subsequently removed by selective etching. However, removal of sacrificial layer material may expose bit lines to etch related damage. Barrier layer material may be removed or damaged and bit line metal may then diffuse and cause unwanted effects including reduced bit line to bit line resistance, or short circuits. In order to protect sides of bit lines when forming air gaps, bit line trenches are initially formed in a sacrificial layer to extend only part-way through the sacrificial layer and a protective layer is deposited in trenches. Trenches are then extended by anisotropic etching to expose vias. Bit lines are then formed in the extended trenches. Etching of sacrificial material is then performed with portions of the protective layer lying along sides of bit lines to shield bit lines (including barrier layer material) from etching. Etching of sacrificial material may stop before reaching a level where bit lines would be exposed (i.e. may stop at some level above the bottom edges of protective layer portions).

An example of a method of forming conductive lines separated by air gaps includes: forming a sacrificial layer over a contact plug; forming a trench in the sacrificial layer above the contact plug leaving a portion of the sacrificial layer over the contact plug; forming a protective layer on a side wall and a bottom of the trench; performing anisotropic etching to remove the protective layer from the bottom of the trench while maintaining the protective layer on the side wall of the trench; subsequently removing the portion of the sacrificial layer over the contact plug; depositing conductive metal in the trench; planarizing to form an individual conductive line in the trench; etching the sacrificial layer using an etch that has a higher etch rate for the sacrificial layer than for the protective layer to form an air gap between the conductive line and a neighboring conductive line; and forming a capping layer to enclose the air gap.

The sacrificial layer may be formed of silicon oxide deposited by Chemical Vapor Deposition (CVD) using Tetraethyl Orthosilicate (TEOS), the protective layer may be a nitride, and the conductive metal may be copper. The protective layer may overlie areas of a top surface of the sacrificial layer on either side of the trench and may protect the areas of the top surface of the sacrificial layer during the anisotropic etching. The etching of the sacrificial layer may form an air gap that has a bottom surface that is no lower than protective layer portions on either side of the air gap. The protective layer portions may extend down to a level that is higher than the contact plug. A barrier layer may be deposited in the trench prior to depositing the conductive metal in the trench, and the conductive metal may be copper. The barrier layer may be formed of one or more of: cobalt (Co), titanium (Ti), titanium nitride (TiN), tantalum (Ta), tantalum nitride (TaN), and ruthenium (Ru). The protective layer may be a metal nitride or metal oxide. The protective layer may be titanium nitride (TiN) or tantalum nitride (TaN). The protective layer may be nitrided silicon. The nitrided silicon may be silicon nitride (SiN), silicon oxynitride (SiON), or silicon carbon nitride (SiCN).

An example of a semiconductor device includes: a first layer of a dielectric; contact plugs that are embedded in the first layer; conductive lines extending over and making contact with the contact plugs, bottom surfaces of the conductive lines lying in contact with the first layer; protective nitride side walls that extend along sides of the conductive lines, the protective side walls extending down to a level that is higher than the bottom surfaces of the conductive lines; air gaps that extend between side walls of neighboring conductive lines; and a capping layer that encloses the air gaps.

The protective nitride side walls may be formed of a metal nitride. The metal nitride may be titanium nitride (TiN) or tantalum nitride (TaN). The protective nitride side walls may be formed of a nitrided silicon. The nitrided silicon may be silicon nitride (SiN), silicon oxynitride (SiON), or silicon carbon nitride (SiCN).

An example of a method of forming bit lines in a NAND memory die includes: forming a contact plug that extends through a first dielectric layer; subsequently forming a second dielectric layer on the first dielectric layer and on the contact plug; etching a plurality of trenches in the second dielectric layer, stopping above an upper surface of the contact plug so that the contact plug is not exposed; subsequently nitriding exposed surfaces of the second dielectric layer; subsequently exposing the contact plug; subsequently depositing a barrier layer in the plurality of trenches, the barrier layer contacting the contact plug; and subsequently depositing a metal over the barrier layer.

The second dielectric layer may be silicon oxide and the nitriding may form a layer of silicon nitride on exposed surfaces of the silicon oxide. Exposing the contact plug may include performing anisotropic etching to remove silicon nitride from bottoms of trenches. The barrier layer may be formed of titanium and the metal may be copper. Subsequent planarizing may form a plurality of bit lines in the plurality of trenches; the second dielectric layer may be selectively removed to leave a plurality of air gaps between the plurality of bit lines; and a cap layer may subsequently be formed to enclose the plurality of air gaps.

An example of a semiconductor device includes: a plurality of bit lines separated by a plurality of air gaps; an individual bit line of the plurality of bit lines contacting a contact plug that extends through an underlying dielectric; a barrier layer protecting the individual bit line, the barrier layer lying in direct contact with the contact plug; and nitride sidewalls extending along sides of the individual bit line in contact with the barrier layer.

The barrier layer may be formed of titanium and the nitride sidewalls may be formed of silicon nitride. The barrier layer may extend below lower ends of the nitride sidewalls. A cap layer may overlie the plurality of bit lines and the plurality of air gaps.

Various aspects, advantages, features and embodiments are included in the following description of examples, which description should be taken in conjunction with the accompanying drawings.

### BRIEF DESCRIPTION OF THE DRAWINGS

FIG. 1 is a block diagram of a prior art memory system.

FIG. 2A is a plan view of a prior art NAND array.

FIG. 2B shows a cross section of the NAND array of FIG. 2A.

FIG. 2C shows another cross section of the NAND array of FIG. 2A.

FIG. 3A illustrates an example of formation of air gaps between bit lines.

FIG. 3B illustrates examples of problems when sacrificial material between bit lines is etched.

FIG. 3C illustrates an etch-resistant barrier layer.

FIG. 4 shows a cross section of a portion of a NAND memory die at an intermediate stage of fabrication including trenches formed in a sacrificial layer.

FIG. 5 shows the structure of FIG. 4 after formation of a protective layer.

FIG. 6 shows the structure of FIG. 5 after further etching to extend trenches.

FIG. 7 shows the structure of FIG. 6 after deposition of a barrier layer and bit line metal.

FIG. 8 shows the structure of FIG. 7 after planarization.

FIG. 9 shows the structure of FIG. 8 after selective etching to remove sacrificial layer material.

FIG. 10 shows the structure of FIG. 9 after formation of a capping layer.

FIG. 11 shows an example of process steps used to form bit lines separated by air gaps.

### DETAILED DESCRIPTION OF EXEMPLARY EMBODIMENTS

### Memory System

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

In other embodiments, types of memory other than the two dimensional and three dimensional exemplary structures described here may be used.

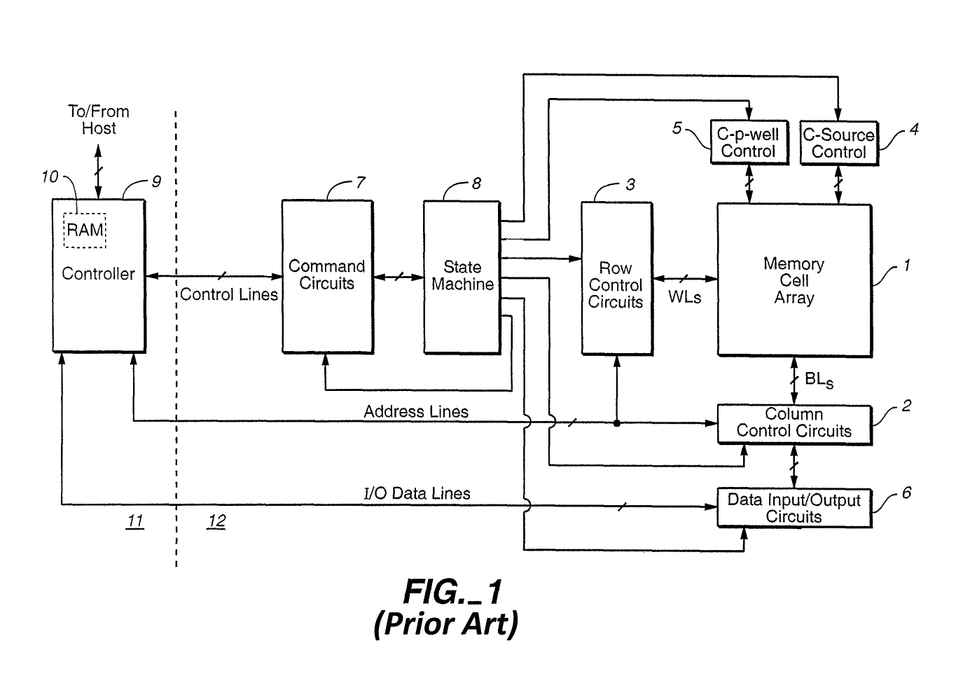

An example of a prior art memory system, which may be modified to include various structures described here, is illustrated by the block diagram of FIG. 1. A planar memory cell array 1 including a plurality of memory cells is controlled by a column control circuit 2, a row control circuit 3, a c-source control circuit 4 and a c-p-well control circuit 5. The memory cell array 1 is, in this example, of the NAND type similar to that described above in the Background. A control circuit 2 is connected to bit lines (BL) of the memory cell array 1 for reading data stored in the memory cells, for determining a state of the memory cells during a program operation, and for controlling potential levels of the bit lines (BL) to promote the programming or to inhibit the programming. The row control circuit 3 is connected to word lines (WL) to select one of the word lines (WL), to apply read voltages, to apply program voltages combined with the bit line potential levels controlled by the column control circuit 2, and to apply an erase voltage coupled with a voltage of a p-type region on which the memory cells are formed. The c-source control circuit 4 controls a common source line (labeled as “c-source” in FIG. 1) connected to the memory cells (M). The c-p-well control circuit 5 controls the c-p-well voltage.

The data stored in the memory cells are read out by the column control circuit 2 and are output to external I/O lines via an I/O line and a data input/output buffer 6. Program data to be stored in the memory cells are input to the data input/output buffer 6 via the external I/O lines, and transferred to the column control circuit 2. The external I/O lines are connected to a controller 9. The controller 9 includes various types of registers and other memory including a volatile random-access-memory (RAM) 10.

The memory system of FIG. 1 may be embedded as part of the host system, or may be included in a memory card, USB drive, or similar unit that is removably insertible into a mating socket of a host system. Such a card may include the entire memory system, or the controller and memory array, with associated peripheral circuits, may be provided in separate cards. The memory system of FIG. 1 may also be used in a Solid State Drive (SSD) or similar unit that provides mass data storage in a tablet, laptop computer, or similar device. Memory systems may be used with a variety of hosts in a variety of different environments. For example, a host may be a mobile device such as a cell phone, laptop, music player (e.g. MP3 player), Global Positioning System (GPS) device, tablet computer, or the like. Such memory systems may be inactive, without power, for long periods during which they may be subject to various conditions including high temperatures, vibration, electromagnetic fields, etc. Memory systems for such hosts, whether removable or embedded, may be selected for low power consumption, high data retention, and reliability in a wide range of environmental conditions (e.g. a wide temperature range). Other hosts may be stationary. For example, servers used for internet applications may use nonvolatile memory systems for storage of data that is sent and received over the internet. Such systems may remain powered up without interruption for extended periods (e.g. a year or more) and may be frequently accessed throughout such periods. Individual blocks may be frequently written and erased so that endurance may be a major concern.

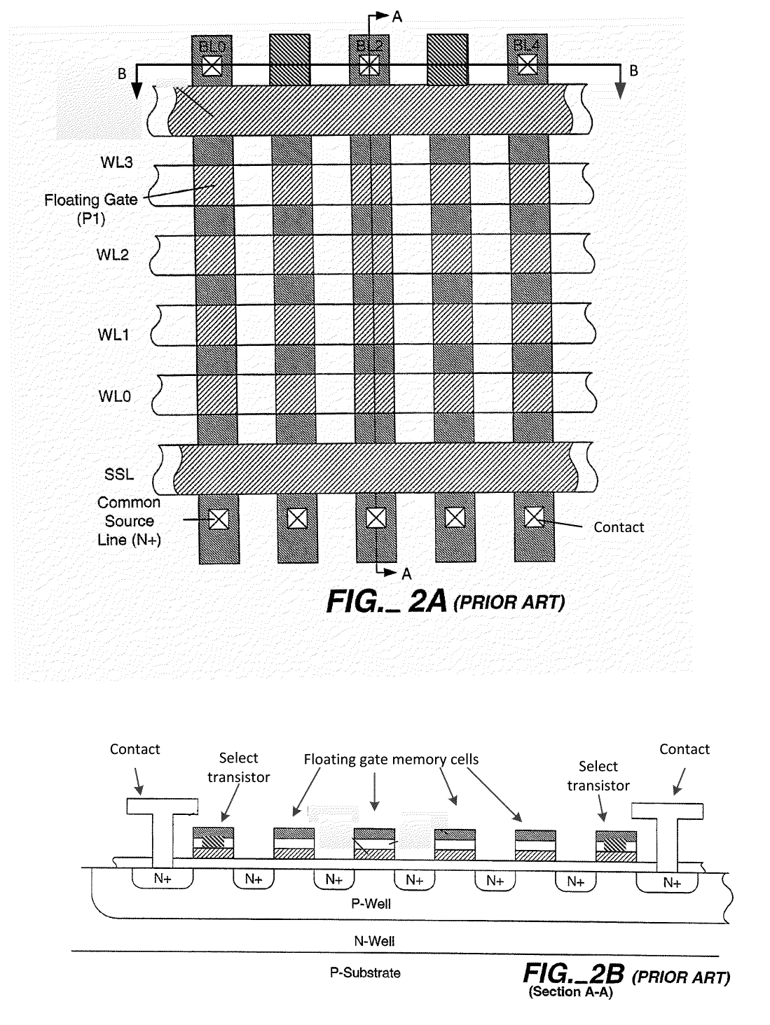

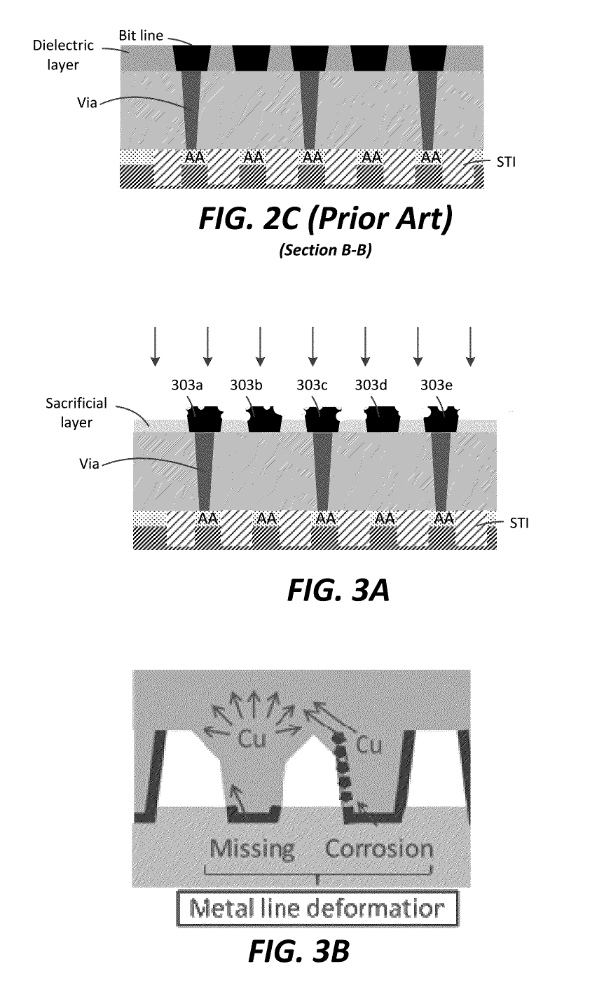

FIGS. 2A-2C show different views of a prior art NAND flash memory. In particular, FIG. 2A shows a plan view of a portion of such a memory array including bit lines and word lines (this is a simplified structure with a small number of word lines and bit lines). FIG. 2B shows a cross section along A-A (along a NAND string) showing individual memory cells that are connected in series. Contact plugs, or vias (the two terms are used interchangeably in the present application) are formed at either end to connect the NAND strings in the memory array to conductive lines (e.g. connecting to bit lines at one end and to a common source line at the other end). Such a via may be formed of metal that is deposited into a contact hole that is formed in a dielectric layer. FIG. 2C shows a cross section along B-B of FIG. 2A. This view shows metal contact plugs extending down through contact holes in a dielectric layer to make contact with active areas (“AA”) in the substrate (i.e. with N+ areas of FIG. 2B). STI regions are located between active areas of different strings to electrically isolate an individual NAND string from its neighbors. Bit lines extend over the memory array in a direction perpendicular to the plane of the cross section shown. Alternating bit lines are connected to vias in the cross section shown. (It will be understood that other vias, that are not visible in the cross section shown, connect the remaining bit lines to other active areas). In this arrangement, locations of vias alternate so that there is more space between vias and thus less risk of contact between vias. Other arrangements are also possible.

As memories become smaller, the spacing between bit lines tends to diminish. Accordingly, capacitive coupling between bit lines tends to increase as technology progresses to ever-smaller dimensions. FIG. 2C shows an example of bit lines formed in a dielectric material. For example, copper bit lines may be formed by a damascene process in which elongated openings, or trenches, are formed in the dielectric layer and then copper is deposited to fill the trenches. When excess copper is removed (e.g. by Chemical Mechanical Polishing, CMP) copper lines remain. A suitable dielectric may be chosen to keep bit line-to-bit line capacitance low.

One way to reduce bit line-to-bit line coupling is to provide an air gap between neighboring bit lines. Thus, rather than maintain dielectric portions between bit lines, the bit lines are formed in a sacrificial layer which is then removed to leave air gaps between bit lines.

Removing sacrificial material between bit lines generally requires some form of etching which may expose bit lines to etch-related damage. While a suitable combination of sacrificial material and etch chemistry may be chosen so that sacrificial material is etched at a higher rate than bit line metal and/or barrier material, some etching or corrosion of bit line metal and/or barrier metal may occur and bit lines may be damaged accordingly.

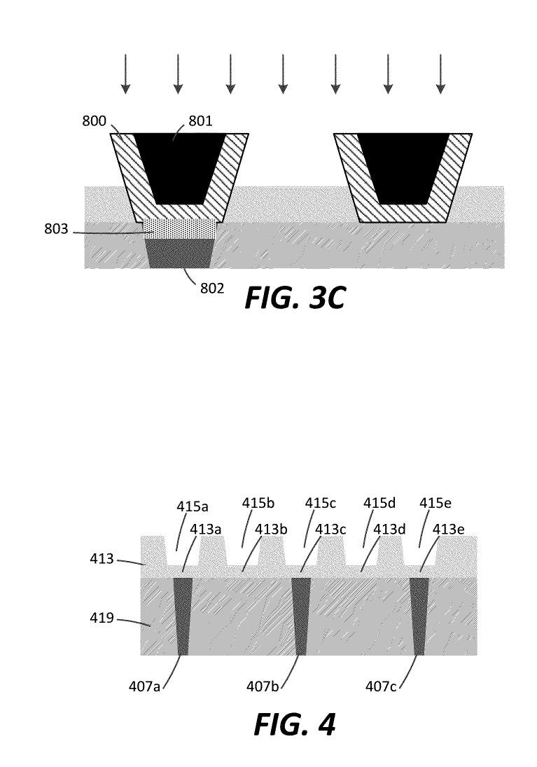

FIG. 3A shows formation of air gaps between bit lines 303a-e by etching away the sacrificial material between bit lines. Such etching may expose bit lines to etch damage (i.e. bit line materials such as copper, and barrier layer materials such as titanium may be corroded or removed by such etching). Damaged bit lines may provide higher resistance or may be shorted out if they are etched through. In addition, over-etching in such a step may undercut bit lines so that the bit lines are no longer attached and may lift off from the substrate resulting in failure.

FIG. 3B illustrates two problems that may occur when etching to remove sacrificial material to form air gaps. A bit line on the left is missing some barrier layer material because the barrier layer material was removed by etching. This allows bit line metal (copper in this example) to migrate and reduce bit line to bit line resistance, in some cases causing a short circuit between neighboring bit line. In another example on the right, a portion of barrier layer is corroded which may also mean that copper is not adequately confined and may form connections between bit lines.

Some barrier layer materials are more etch-resistant than other materials. For a given etch chemistry, a suitable barrier material may be found that has a low etch rate compared with the sacrificial layer material so that the sacrificial material can be selectively removed without damaging the barrier layer (or the metal that is protected by the barrier layer).

FIG. 3C shows an example of bit lines that use a layer of etch-resistant barrier material 800. In this case, sacrificial layer material is removed without damage to bit lines. The barrier layer material in this example may be titanium nitride (TiN), tantalum nitride (TaN), or other suitable material. While etch-resistant materials may provide good protection from etching, such materials may not be ideal barrier layer materials in other ways. For example, such nitrides may not be good conductors and formation of nitride layers on an exposed metal via may cause nitridation of the via metal. Such nitrided metal may have significant resistance. In the location shown, there is no direct contact between the bit line metal 801 and the underlying via 802. Thus, electrical current flowing between via 802 (contact plug) and the bit line metal 801 passes through the portion of barrier layer material 800 that overlies the via and through a portion of metal nitride 803 (e.g. tungsten nitride where via is formed of tungsten that is exposed to nitridation). Even though these layers may be thin, they may add significant resistance.

FIG. 4 shows an example of a portion of a memory die at an intermediate stage of fabrication with vias 407a-c extending through dielectric layer 419 which may be formed of silicon oxide or other suitable material. Underlying structures such as STI portions and active areas are omitted from this and subsequent figures for clarity. It will be understood that any suitable circuits, including planar NAND flash memory, may underlie the portions shown. A sacrificial layer 413 extends over dielectric layer 419 and is patterned to form trenches 415a-e where bit lines are to be formed (overlying vias 407a-c). Trenches 415a-e do not extent all the way through sacrificial layer 413 and do not expose vias 407a-c. Instead, trenches 415a-e extend a depth that is less than the thickness of sacrificial layer 413 to leave sacrificial layer portions 413a-e under trenches 415a-e. Thus, portions of sacrificial material 413a, 413c, and 413e overlie vias 407a-c as shown.

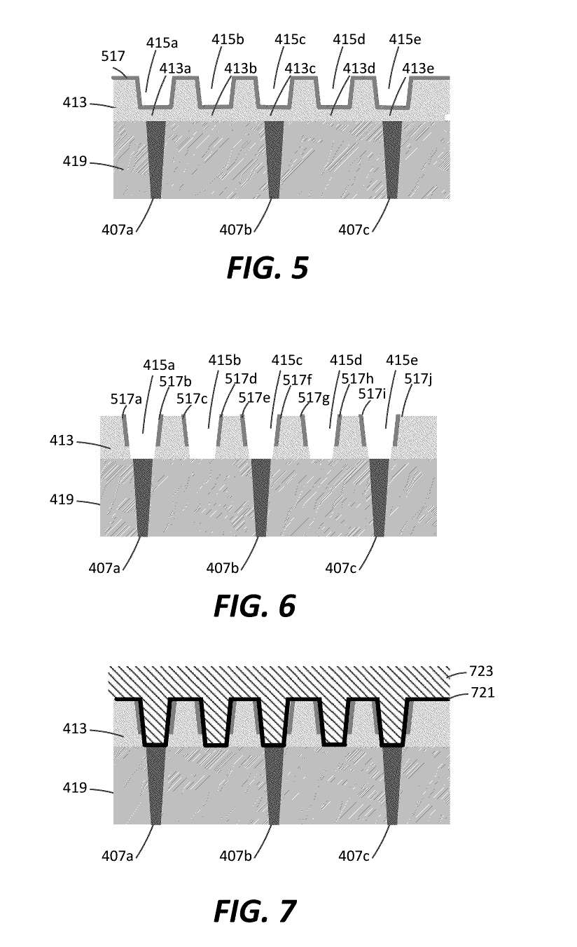

FIG. 5 shows the example of FIG. 4 after formation of a protective layer 517 over exposed surfaces of sacrificial layer 413. It can be seen that the protective layer 517 extends along sides and bottom surfaces of trenches 415a-e. Protective layer 517 also extends along the top surface of sacrificial layer 413 in areas between trenches. Protective layer 517 may be formed of a suitable material that can provide etch protection for bit lines at a later stage. In this example, protective layer 517 consists of nitride that is formed by nitriding exposed surfaces of sacrificial layer 517 or by deposition. For example, where a sacrificial layer is formed of silicon, a protective layer of silicon nitride may be formed by nitriding exposed silicon. Where a sacrificial layer is formed of silicon oxide, a protective layer of silicon oxynitride may be formed by nitriding exposed silicon oxide. Other metal nitrides such as tantalum nitride (TaN) may also be used and may be deposited using any appropriate technique (e.g. CVD). In addition to metal nitrides, other materials such as oxides may be used to form a protective layer. It can be seen that the presence of sacrificial portions 413a-e protects vias 407a-c when the protective layer is formed so that nitridation of vias does not occur during formation of the protective layer 517.

FIG. 6 shows the structure of FIG. 5 after anisotropic etching (e.g. by Reactive Ion Etching “RIE”). In this example, protective layer 517 is etched through where it lies on substantially horizontal surfaces such as at bottoms of trenches 415a-e and on areas of the top surface of sacrificial layer 413 between trenches. However, on sidewalls of trenches 415a-e, portions 517a-j of protective layer 517 remain. Etching continues to remove some material of sacrificial layer 413. Specifically, etching continues to remove sacrificial layer portions 413a-e from bottoms of trenches 415a-e thereby exposing vias 407a-c.

FIG. 7 shows the structure of FIG. 6 after deposition of a barrier layer 721 and bit line metal 723. Barrier layer 721 may be substantially conformal so that it extends along sides and bottom surfaces of trenches. In particular, barrier layer 721 lies in contact with vias 407a-c at bottoms of trenches. However, in this example, barrier layer 721 is formed of a material with a relatively low resistance. Examples of suitable barrier layer materials include titanium (Ti), cobalt (Co), titanium nitride (TiN), tantalum (Ta), tantalum nitride (TaN), ruthenium (Ru), indium (In), iridium (Ir), and rhodium (Rh). Other suitable barrier materials may also be selected. As will be seen, barrier layer material is not exposed to etching during removal of sacrificial layer material in this example. Thus, the barrier layer material may be selected largely without regard to its etch-resistance and this provides a wider range of viable barrier layer materials including materials that are not particularly etch resistant. For example, materials other than nitride may be used so that nitridation of vias does not occur and overall resistance is lowered compared with structures that include nitrided vias. Bit line metal 723 may be copper (Cu), Aluminum (Al), titanium (Ti), tungsten (W) of other suitable metal. Bit line metal may be formed by Physical Vapor Deposition (PVD), Chemical Vapor Deposition (CVD), Atomic Layer Deposition (ALD), electroplating, or other suitable technique.

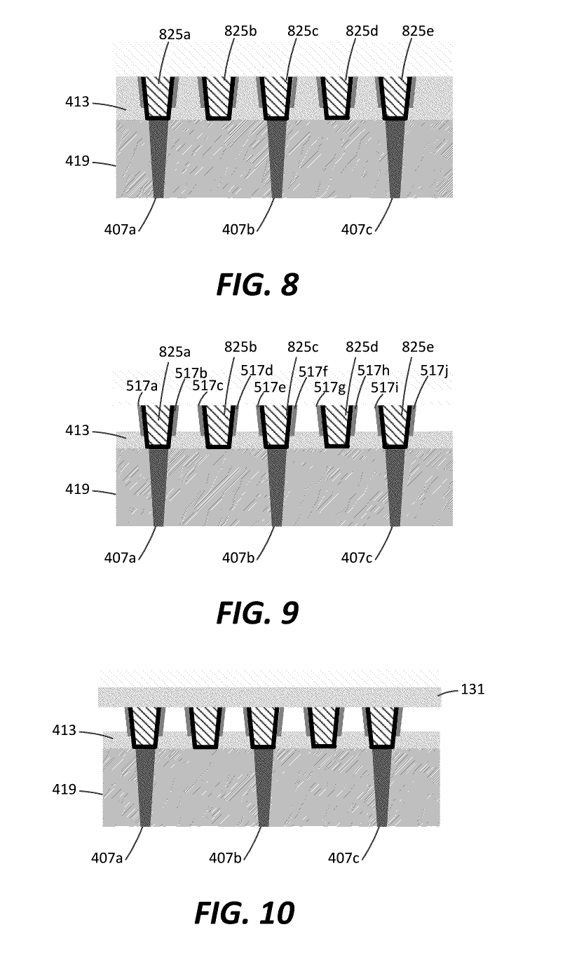

FIG. 8 shows the structure of FIG. 7 after planarization to form separate bit lines 825a-e. Planarization may use Chemical Mechanical Polishing (CMP) and/or etching to remove excess bit line metal to leave separate bit lines 825a-e in trenches. Planarization exposes remaining portions of sacrificial layer 413 at locations between bit lines 825a-e.

FIG. 9 shows the structure of FIG. 8 after etching to remove sacrificial layer 413 from between bit lines 825a-e. In this example, portions of protective layer portions 517a-j lie along sides of bit lines 825a-e during this etch so that sides of bit lines 825a-e are protected. Protective layer portions are formed of a suitable material (e.g. a nitride) that is highly etch-resistant and thus remains in place throughout etching. Sides of bit lines 825a-e are not directly exposed to etching during this etch step so that the materials of the bit lines (bit line metal and barrier layer material) may be formed of materials that are chosen for other properties (e.g. electrical properties) with little or no regard to their etch rates. Examples of suitable selective etch processes for selective removal of sacrificial material include wet etching using hydrofluoric acid (HF), and dry etching using HF gas, nitrogen trifluoride (NF3) or other gas. Etching of sacrificial layer 413 may stop at a level that is higher than the bottoms of portions of protective layer portions 517a-j (and higher than tops of vias 407a-c) so that barrier layer material is not exposed to this etching (i.e. etching of sacrificial layer 413 stops at a level above the level of original trenches 415a-e as shown in FIG. 5). Stopping etching at this point ensures that bit lines are adequately attached and ensures that there is no etching under bit lines which could cause bit lines to lift off. This etching establishes air gaps that extend for a significant part of the volume between bit lines. Where portions of protective layer extend to near the bottom of the bit lines, air gaps can similarly extend to near the bottom of the bit lines so that air gaps

FIG. 10 shows the structure of FIG. 9 after subsequent formation of an air gap capping layer 131. An air gap capping layer may be formed of a suitable material that tends to grow at a high rate to form mushroom like growth at tops of bit lines that pinch off gaps between bit lines and thereby encloses the air gaps between bit lines. An example of a suitable material for such an air gap capping layer is silicon carbon nitride (SiCN).

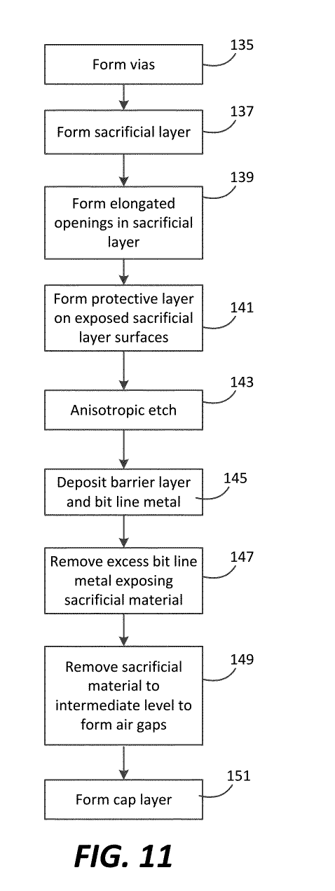

FIG. 11 illustrates an example of a series of steps that may be used to form bit lines with protection for barrier layer material. Vias (contact plugs) are formed 135 in a first dielectric layer (e.g. by etching holes and filling holes with a suitable metal such as tungsten). Then, a sacrificial layer is formed 137 extending over the first dielectric layer and over top surfaces of vias. Elongated openings, or trenches, are then formed 139 in the sacrificial layer at locations where bit lines are to be formed (trenches extend over vias where contact is to be formed between vias and bit lines). These trenches do not extend down to the tops of vias but instead stop some distance above so that a portion of sacrificial layer material remains over top surfaces of vias. A protective layer is then formed 141 on exposed surfaces of the sacrificial layer including sides and bottom surfaces of trenches, for example, by nitriding the material of the sacrificial layer. Anisotropic etching 143 then extends trenches and exposes contact plugs. Subsequently a barrier layer and bit line metal are deposited 145 so that trenches are filled. Excess bit line metal is then removed 147 by planarizing (e.g. CMP) to form separate bit lines in trenches. Planarization may also remove some barrier layer material to expose sacrificial layer material between bit lines. Etching is then performed 149 to remove exposed sacrificial material down to an intermediate level that ensures that barrier layer material along sides of bit lines is not exposed to etching. Subsequently, a cap layer is formed 151 to cap air gaps between bit lines.

### CONCLUSION

Although the various aspects have been described with respect to examples, it will be understood that protection within the full scope of the appended claims is appropriate.

1. A method of forming conductive lines separated by air gaps comprising:
forming a sacrificial layer over a contact plug;
forming a trench in-part-way through the sacrificial layer above the contact plug leaving a portion of the sacrificial layer located under the trench and over the contact plug;
forming a protective layer on a side wall and a bottom of the trench;
performing anisotropic etching to remove the protective layer from the bottom of the trench while maintaining the protective layer on the side wall of the trench;
subsequently removing the portion of the sacrificial layer over the contact plug;
subsequently depositing conductive metal in the trench;
planarizing to form an individual conductive line in the trench;
etching the sacrificial layer using an etch that has a higher etch rate for the sacrificial layer than for the protective layer to form an air gap between the conductive line and a neighboring conductive line; and
forming a capping layer to enclose the air gap.

2. The method of claim 1, wherein the sacrificial layer is formed of silicon oxide deposited by Chemical Vapor Deposition (CVD) using Tetraethyl Orthosilicate (TEOS), the protective layer is a nitride, and the conductive metal is copper.

3. The method of claim 1, wherein the protective layer overlies areas of a top surface of the sacrificial layer on either side of the trench and protects the areas of the top surface of the sacrificial layer during the anisotropic etching.

4. The method of claim 1, wherein the etching of the sacrificial layer forms an air gap that has a bottom surface that is no lower than protective layer portions on either side of the air gap.

5. The method of claim 4, wherein the protective layer portions extend down to a level that is higher than the contact plug.

6. The method of claim 1 further comprising:
depositing a barrier layer in the trench prior to depositing the conductive metal in the trench, and wherein the conductive metal is copper.

7. The method of claim 6, wherein the barrier layer is formed of one or more of cobalt (Co), titanium (Ti), titanium nitride (TIN), tantalum (Ta), tantalum nitride (TaN), and ruthenium (Ru).

8. The method of claim 1, wherein the protective layer is a metal nitride or metal oxide.

9. The method of claim 8, wherein the protective layer is titanium nitride (TiN) or tantalum nitride (TaN).

10. The method of claim 1, wherein the protective layer is a nitrided silicon.

11. The method of claim 10, wherein the nitrided silicon is silicon nitride (SiN), silicon oxynitride (SiON), or silicon carbon nitride (SiCN).

12-16. (canceled)

17. A method of forming bit lines in a NAND memory die, comprising:
forming a contact plug that extends through a first dielectric layer;
subsequently forming a second dielectric layer on the first dielectric layer and on the contact plug;
etching a plurality of trenches part-way through the second dielectric layer, stopping above an upper surface of the contact plug so that the contact plug is not exposed;
subsequently nitriding exposed surfaces of the second dielectric layer;
subsequently exposing the contact plug;
subsequently depositing a barrier layer in the plurality of trenches, the barrier layer contacting the contact plug; and
subsequently depositing a metal over the barrier layer.

18. The method of claim 17, wherein the second dielectric layer is silicon oxide and the nitriding forms a layer of silicon nitride on exposed surfaces of the silicon oxide.

19. The method of claim 17, wherein exposing the contact plug includes performing anisotropic etching to remove silicon nitride from bottoms of trenches.

20. The method of claim 17, wherein the barrier layer is formed of titanium and the metal is copper.

21. The method of claim 17, further comprising:
subsequently planarizing to form a plurality of bit lines in the plurality of trenches;
subsequently selectively removing the second dielectric layer to leave a plurality of air gaps between the plurality of bit lines; and
subsequently forming a cap layer to enclose the plurality of air gaps.

22-25. (canceled)

26. The method of claim 1 wherein the removing the portion of the sacrificial layer over the contact plug exposes at least a central area of an upper surface of the contact plug.

27. The method of claim 5 wherein the bottom surface of the air gap is higher than the level.

28. The method of claim 27 wherein a remaining portion of the sacrificial layer remains under the air gap and the remaining portion extends under the protective portion.

29. The method of claim 28 wherein the remaining portion lies in direct physical contact with the conductive metal, or in direct physical contact with a bather layer that lies in direct physical contact with the conductive metal.

30. The method of claim 17 wherein the first dielectric layer consists comprises a first thickness of a first material, the second dielectric layer comprises a second thickness of a second material, and wherein etching part-way through the second dielectric layer removes second material down to a depth that is less than the second thickness and thereby leaving a portion of the second material covering an upper surface of the contact plug.
